(19) United States
(12) Patent Application Publication
(10) Pub. No.: US 2024/0040859 A1
(43) Pub. Date: Feb. 1, 2024

(54) DISPLAY APPARATUS

(71) Applicant: SAMSUNG DISPLAY CO., LTD., YONGIN-SI (KR)

(72) Inventors: Jonghyun CHOI, YONGIN-SI (KR); Minjeong OH, YONGIN-SI (KR); Kijune LEE, YONGIN-SI (KR)

(21) Appl. No.: 18/135,289

(22) Filed: Apr. 17, 2023

(30) Foreign Application Priority Data
Aug. 1, 2022 (KR) 10-2022-0095686

(51) Int. Cl. H10K 59/124; H10K 59/131

(52) U.S. Cl. CPC H10K 59/124; H10K 59/131

(57) ABSTRACT

A display apparatus includes a substrate comprising a sub-pixel area. A pixel circuit layer is located on the substrate and defines a pixel circuit overlapping the sub-pixel area. A display element layer is located on the pixel circuit layer and comprises a display element. The pixel circuit layer comprises an inorganic insulating layer located on the substrate and comprising a groove. An organic insulating layer is located on the inorganic insulating layer. A plurality of conductive patterns is located between the inorganic insulating layer and the organic insulating layer. The plurality of conductive patterns comprises a first conductive pattern connected to a data line. The data line is located on the organic insulating layer. The groove is located between the first conductive pattern and adjacent conductive patterns of the plurality of conductive patterns. The adjacent conductive patterns are spaced apart from the first conductive pattern.

### CROSS-REFERENCE TO RELATED APPLICATION

This application is based on and claims priority under 35 U.S.C. § 119 to Korean Patent Application No. 10-2022-0095686, filed on Aug. 1, 2022 in the Korean Intellectual Property Office, the disclosure of which is incorporated by reference in its entirety herein.

### 1. TECHNICAL FIELD

One or more embodiments relate to a display apparatus.

### 2. DISCUSSION OF RELATED ART

Display apparatuses are electronic devices that display images. A display apparatus may be used as a display for a relatively small product, such as a mobile phone or may be used as a display for a relatively large product such as a television.

A display apparatus may include a plurality of sub-pixels that emit light by receiving electrical signals to display an image to a user. Each of the plurality of sub-pixels may include a display element.

As display apparatuses are being applied to increasingly diverse types of electronic products, various designs are being developed to increase the quality of display apparatuses. For example, display apparatuses having an increased resolution or increased resistance to defects from external impacts are being developed.

### SUMMARY

One or more embodiments of the present disclosure include a display apparatus in which defects due to external impact are prevented or reduced and a high resolution is maintained.

Additional aspects will be set forth in part in the description which follows and, in part, will be apparent from the description, or may be learned by practice of the presented embodiments.

According to an embodiment of the present disclosure, a display apparatus includes a substrate comprising a sub-pixel area. A pixel circuit layer is located on the substrate and defines a pixel circuit overlapping the sub-pixel area. A display element layer is located on the pixel circuit layer and comprises a display element. The pixel circuit layer comprises an inorganic insulating layer located on the substrate and comprising a groove. An organic insulating layer is located on the inorganic insulating layer. A plurality of conductive patterns is located between the inorganic insulating layer and the organic insulating layer. The plurality of conductive patterns comprises a first conductive pattern connected to a data line. The data line is located on the organic insulating layer. The groove is located between the first conductive pattern and adjacent conductive patterns of the plurality of conductive patterns. The adjacent conductive patterns are spaced apart from the first conductive pattern.

In an embodiment, the groove is filled with the organic insulating layer. The groove overlaps the display element.

In an embodiment, the inorganic insulating layer may include a plurality of inorganic insulating patterns spaced apart from each other by the groove, and a lower inorganic insulating layer located between the substrate and the plurality of inorganic insulating patterns.

In an embodiment, the pixel circuit layer may further include a first semiconductor layer located on the substrate. The first semiconductor layer includes a silicon semiconductor. The lower inorganic insulating layer includes at least one insulating layer located between the first semiconductor layer and the plurality of inorganic insulating patterns.

In an embodiment, the pixel circuit layer may further include a second semiconductor layer located on the substrate. The second semiconductor layer includes an oxide semiconductor. The lower inorganic insulating layer includes at least one insulating layer located between the second semiconductor layer and the plurality of inorganic insulating patterns.

In an embodiment, the pixel circuit layer may further include a semiconductor layer located on the substrate and a gate conductive layer located on the semiconductor layer. At least a portion of the gate conductive layer is exposed through the groove of the inorganic insulating layer.

In an embodiment, the pixel circuit layer may further include an upper conductive pattern located on the organic insulating layer and connected to the display element, and an upper organic insulating layer located on the upper conductive pattern. The plurality of conductive patterns includes a second conductive pattern connected to a driving voltage line and a third conductive pattern connected to the upper conductive pattern. The groove is located between the second conductive pattern and the third conductive pattern.

In an embodiment, the display element layer may further include a pixel electrode located on the upper organic insulating layer. The first conductive pattern electrically connects the data line to a switching transistor. The second conductive pattern electrically connects the driving voltage line to an operation control transistor. The third conductive pattern electrically connects the pixel electrode to an emission control transistor.

In an embodiment, the sub-pixel area may include a first sub-pixel area and a second sub-pixel area each surrounded by the groove of the inorganic insulating layer. The pixel circuit includes a first pixel circuit overlapping the first sub-pixel area and a second pixel circuit overlapping the second sub-pixel area. A connection electrode is located on the organic insulating layer. The connection electrode connects the first pixel circuit and the second pixel circuit to each other.

In an embodiment, the display element layer may further include an intermediate layer located on the pixel electrode, and a counter electrode covering the intermediate layer.

According to an embodiment of the present disclosure, a display apparatus includes a substrate including a sub-pixel area. An inorganic insulating layer is located on the substrate. The inorganic insulating layer overlaps the sub-pixel area and includes a groove. A plurality of conductive patterns is located on the inorganic insulating layer. An organic insulating layer covers the inorganic insulating layer and the plurality of conductive patterns. The plurality of conductive patterns includes a first conductive pattern connected to a data line that is located on the organic insulating layer, a second conductive pattern connected to a driving voltage line, and a third conductive pattern connected to an upper conductive pattern. The first conductive pattern, the second conductive pattern, and the third conductive pattern are each surrounded by the groove.

In an embodiment, the inorganic insulating layer may include a plurality of inorganic insulating patterns spaced apart from each other by the groove. The first conductive pattern, the second conductive pattern, and the third conductive pattern are respectively located on the plurality of inorganic insulating patterns.

In an embodiment, the organic insulating layer may be located in the groove between the plurality of inorganic insulating patterns.

In an embodiment, the display apparatus may further include a first semiconductor layer located on the substrate. The first semiconductor layer includes a silicon semiconductor. A second semiconductor layer is located on the substrate.

The second semiconductor layer includes an oxide semiconductor. The first conductive pattern, the second conductive pattern, and the third conductive pattern overlap the first semiconductor layer.

In an embodiment, the first semiconductor layer may include a source region of a switching transistor connected to the first conductive pattern, a source region of an operation control transistor connected to the second conductive pattern, and a drain region of an emission control transistor connected to the third conductive pattern.

In an embodiment, the driving voltage line and the upper conductive pattern may be located on the organic insulating layer.

In an embodiment, the display apparatus may further include an upper organic insulating layer located on the organic insulating layer, and a display element layer located on the upper organic insulating layer. The display element layer includes a display element. The groove of the inorganic insulating layer overlaps the display element.

In an embodiment, the display element layer may further include a pixel electrode located on the upper organic insulating layer and connected to the upper conductive pattern, an intermediate layer located on the pixel electrode, and a counter electrode covering the intermediate layer.

In an embodiment, the sub-pixel area may include a first sub-pixel area overlapping a first pixel circuit and a second sub-pixel area overlapping a second pixel circuit. The first sub-pixel area and the second sub-pixel area are each surrounded by the groove. The first pixel circuit and the second pixel circuit are located on the organic insulating layer. A connection electrode is located on the organic insulating layer and crosses the groove. The connection electrode connects the first pixel circuit and the second pixel circuit to each other.

In an embodiment, the display apparatus may further include a buffer layer located between the substrate and the first semiconductor layer. The groove surrounds the sub-pixel area exposes a portion of the buffer layer.

### BRIEF DESCRIPTION OF THE DRAWINGS

The above and other aspects, features, and advantages of certain embodiments will be more apparent from the following description taken in conjunction with the accompanying drawings, in which:

FIG. 1 is a plan view schematically illustrating a display apparatus, according to an embodiment;

FIG. 2 is an equivalent circuit diagram illustrating a sub-pixel provided in a display apparatus, according to an embodiment;

FIG. 3 is a plan view schematically illustrating a sub-pixel area and a pixel circuit layer of a display apparatus, according to an embodiment;

FIGS. 4A through 4G are plan views partially illustrating elements of FIG. 3;

FIG. 5 is a cross-sectional view schematically illustrating the display apparatus taken along line I-I′ of FIG. 3;

FIGS. 6A and 6B are each a cross-sectional view illustrating a portion marked by a dashed line of FIG. 5;

FIG. 7 is a cross-sectional view schematically illustrating the display apparatus taken along line II-II′ of FIG. 3; and

FIG. 8 is a cross-sectional view schematically illustrating the display apparatus taken along line A-A′ of FIG. 1.

### DETAILED DESCRIPTION OF EMBODIMENTS

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not necessarily limited to the following embodiments and may be embodied in various forms.

Reference will now be made in detail to embodiments, examples of which are illustrated in the accompanying drawings, and in the drawings, the same elements are denoted by the same reference numerals, and thus a repeated description thereof will be omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be further understood that the terms “comprises” or “comprising” used herein specify the presence of stated features or components, but do not preclude the presence or addition of one or more other features or components.

It will be further understood that, when a layer, region, or component is referred to as being “on” another layer, region, or component, it may be directly on the other layer, region, or component, or may be indirectly on the other layer, region, or component with intervening layers, regions, or components therebetween. When a layer, region, or component is referred to as being “directly on” another layer, region, or component, no intervening layers, regions, or components may be present.

Sizes of components in the drawings may be exaggerated or contracted for convenience of explanation. For example, because sizes and thicknesses of elements in the drawings may be arbitrarily illustrated for convenience of explanation, the disclosure is not necessarily limited thereto.

When a certain embodiment may be implemented differently, a specific process order may be different from the described order. For example, two consecutively described processes may be performed substantially at the same time or may be performed in an order opposite to the described order.

It will be understood that when a layer, region, or component is referred to as being “connected,” the layer, the region, or the component may be directly connected or may be indirectly connected with intervening layers, regions, or components therebetween. For example, when layers, regions, or components are referred to as being “electrically connected,” the layers, the regions, or the components may be directly electrically connected, or may be indirectly electrically connected with intervening layers, regions, or components therebetween.

A display apparatus that is a device for displaying an image may include a portable mobile device such as a game player, a multimedia device, or a mini-PC. Examples of the display apparatus described below may include a liquid-crystal display, an electrophoretic display, an organic light-emitting display, an inorganic light-emitting display, a field-emission display, a surface-conduction electron-emitter display, a quantum dot display, a plasma display, and a cathode ray display. Although an organic light-emitting display apparatus is used as the display apparatus according to an embodiment for convenience of explanation, any of various display apparatuses as described above may be used.

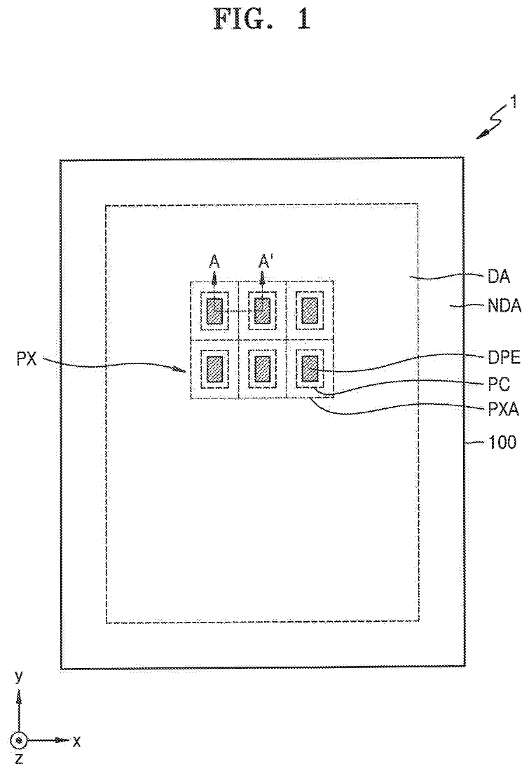

FIG. 1 is a plan view illustrating a display apparatus 1, according to an embodiment.

Referring to FIG. 1, the display apparatus 1 may include a substrate 100, a pixel circuit PC, and a display element DPE. The substrate 100 may include a display area DA and a non-display area NDA. The display apparatus 1 may display an image in the display area DA. The non-display area NDA may be an area where an image is not displayed by the display apparatus 1.

The display area DA may include a sub-pixel area PXA. In an embodiment, the display area DA may include a plurality of sub-pixel areas PXA. In an embodiment, the plurality of sub-pixel areas PXA may be arranged in a first direction and a second direction intersecting the first direction. A right angle, an obtuse angle, or an acute angle may be formed between the first direction and the second direction. The following will be described as an embodiment in which the first direction and the second direction are orthogonal to each other. For example, the first direction may be an x direction or a −x direction of FIG. 1. The second direction may be a y direction or a −y direction of FIG. 1. However, embodiments of the present disclosure are not necessarily limited thereto.

The pixel circuit PC may transmit an electrical signal to the display element DPE, and may control the display element DPE. In an embodiment, the pixel circuit PC may be located in the sub-pixel area PXA. In an embodiment, a plurality of pixel circuits PC may be respectively located in a plurality of sub-pixel areas PXA. In this embodiment, the sub-pixel area PXA may be defined as an area where the pixel circuit PC is located. In an embodiment, the pixel circuit PC may include at least one thin-film transistor and at least one storage capacitor.

The display element DPE may emit light, and may be located in the sub-pixel area PXA. In an embodiment, a plurality of display elements DPE may be respectively located in a plurality of sub-pixel areas PXA. For example, the sub-pixel area PXA may be defined as an area where the display element DPE is located.

The display element DPE may receive an electrical signal from the pixel circuit PC, and may emit light according to the electrical signal. In this embodiment, the display element DPE may define a sub-pixel PX. Since the plurality of display elements DPE may emit light, the display apparatus 1 may display an image in the display area DA.

In an embodiment, the display element DPE may be an organic light-emitting diode including an organic emission layer. Alternatively, the display element DPE may be a light-emitting diode (LED). The light-emitting diode may have a micro-scale or nano-scale size. For example, the light-emitting diode may be a micro light-emitting diode. Alternatively, the light-emitting diode may be a nanorod light-emitting diode. The nanorod light-emitting diode may include gallium nitride (GaN). In an embodiment, a color conversion layer may be located on the nanorod light-emitting diode. The color conversion layer may include quantum dots. Alternatively, the display element DPE may be a quantum dot light-emitting diode including a quantum dot emission layer.

Alternatively, the display element DPE may be an inorganic light-emitting diode including an inorganic semiconductor. The following will be described in detail assuming as an embodiment in which the display element DPE is an organic light-emitting diode for convenience of explanation.

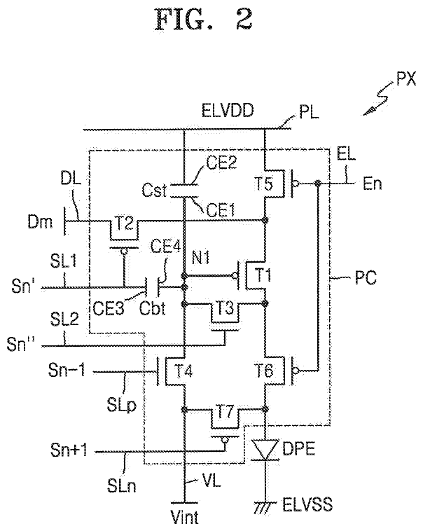

FIG. 2 is an equivalent circuit diagram illustrating the sub-pixel PX provided in a display apparatus, according to an embodiment.

Referring to FIG. 2, a pixel circuit PC may include a driving thin-film transistor T1, a switching thin-film transistor T2, a compensation thin-film transistor T3, a first initialization thin-film transistor T4, an operation control thin-film transistor T5, an emission control thin-film transistor T6, a second initialization thin-film transistor T7, a storage capacitor Cst, and a boost capacitor Cbt.

Although signal lines, an initialization voltage line VL, and a driving voltage line PL are provided in each pixel circuit PC in FIG. 2, embodiments of the present disclosure are not necessarily limited thereto. For example, in another embodiment, at least one of the signal lines and/or the initialization voltage line VL may be shared by neighboring pixel circuits.

In an embodiment, a first portion of the plurality of thin-film transistors may be provided as n-channel MOSFETs (NMOSs) and a remaining portion of the plurality of thin-film transistors may be provided as p-channel MOSFETs (PMOSs).

In an embodiment, the compensation thin-film transistor T3 and the first initialization thin-film transistor T4 from among the plurality of thin-film transistors (e.g., T1 through T7) may be provided as NMOSs and the remaining portion (e.g., T1, T2 and T5-T7) of the plurality of thin-film transistors may be provided as PMOSs.

In an embodiment, the compensation thin-film transistor T3, the first initialization thin-film transistor T4, and the second initialization thin-film transistor T7 from among the plurality of thin-film transistors (e.g., T1 through T7) may be provided as NMOSs and the remaining portion of the plurality of thin-film transistors may be provided as PMOSs. Alternatively, only one of the plurality of thin-film transistors (e.g., T1 through T7) may be provided as an NMOS and the remaining portion of the plurality of thin-film transistors may be provided as PMOSs. Alternatively, all of the plurality of thin-film transistors (e.g., T1 through T7) may be provided as NMOSs.

The signal lines may include a first scan line SL1 that transmits a first scan signal Sn′, a second scan line SL2 that transmits a second scan signal Sn″, a previous scan line SLp that transmits a previous scan signal Sn−1 to the first initialization thin-film transistor T4, an emission control line EL that transmits an emission control signal En to the operation control thin-film transistor T5 and the emission control thin-film transistor T6, a next scan line SLn that transmits a next scan signal Sn+1 to the second initialization thin-film transistor T7, and a data line DL that transmits a data signal Dm.

In an embodiment, the driving voltage line PL may transmit a first power supply voltage ELVDD to the driving thin-film transistor T1, and the initialization voltage line VL may transmit an initialization voltage Vint for initializing the driving thin-film transistor T1 and a pixel electrode.

In an embodiment, a driving gate electrode of the driving thin-film transistor T1 may be electrically connected to a first electrode CE1 of the storage capacitor Cst, a driving source electrode of the driving thin-film transistor T1 may be electrically connected to the driving voltage line PL via the operation control thin-film transistor T5, and a driving drain electrode of the driving thin-film transistor T1 may be electrically connected to the pixel electrode of the display element DPE via the emission control thin-film transistor T6. The driving thin-film transistor T1 may receive the data signal Dm according to a switching operation of the switching thin-film transistor T2 and may supply driving current to the display element DPE.

A switching gate electrode of the switching thin-film transistor T2 may be electrically connected to the first scan line SL1. A switching source electrode of the switching thin-film transistor T2 may be electrically connected to the data line DL. A switching drain electrode of the switching thin-film transistor T2 may be electrically connected to the driving source electrode of the driving thin-film transistor T1, and may be electrically connected to a driving voltage line PL via the operation control thin-film transistor T5. The switching thin-film transistor T2 may be turned on according to the first scan signal Sn′ received through the first scan line SL1, and may perform a switching operation of transmitting the data signal Dm transmitted through the data line DL to the driving source electrode of the driving thin-film transistor T1.

A compensation gate electrode of the compensation thin-film transistor T3 may be electrically connected to the second scan line SL2. A compensation drain electrode of the compensation thin-film transistor T3 may be electrically connected to the driving drain electrode of the driving thin-film transistor T1, and may be connected to the pixel electrode of the display element DPE via the emission control thin-film transistor T6. A compensation source electrode of the compensation thin-film transistor T3 may be electrically connected to the first electrode CE1 of the storage capacitor Cst and the driving gate electrode of the driving thin-film transistor T1. Also, the compensation source electrode of the compensation thin-film transistor T3 may be electrically connected to a first initialization drain electrode of the first initialization thin-film transistor T4.

The compensation thin-film transistor T3 may be turned on according to the second scan signal Sn″ received through the second scan line SL2, and may diode-connect the driving thin-film transistor T1 by electrically connecting the driving gate electrode and the driving drain electrode of the driving thin-film transistor T1.

A first initialization gate electrode of the first initialization thin-film transistor T4 may be electrically connected to the previous scan line SLp. A first initialization source electrode of the first initialization thin-film transistor T4 may be electrically connected to a second initialization source electrode of the second initialization thin-film transistor T7 and the initialization voltage line VL. The first initialization drain electrode of the first initialization thin-film transistor T4 may be electrically connected to the first electrode CE1 of the storage capacitor Cst, the compensation source electrode of the compensation thin-film transistor T3, and the driving gate electrode of the driving thin-film transistor T1. The first initialization thin-film transistor T4 may be turned on according to the previous scan signal Sn−1 received through the previous scan line SLp and may perform an initialization operation of initializing a voltage of the driving gate electrode of the driving thin-film transistor T1 by transmitting the initialization voltage Vint to the driving gate electrode of the driving thin-film transistor T1.

An operation control gate electrode of the operation control thin-film transistor T5 may be electrically connected to the emission control line EL. An operation control source electrode of the operation control thin-film transistor T5 may be electrically connected to the driving voltage line PL. An operation control drain electrode of the operation control thin-film transistor T5 may be electrically connected to the driving source electrode of the driving thin-film transistor T1 and the switching drain electrode of the switching thin-film transistor T2.

An emission control gate electrode of the emission control thin-film transistor T6 may be electrically connected to the emission control line EL. An emission control source electrode of the emission control thin-film transistor T6 may be connected to the driving drain electrode of the driving thin-film transistor T1 and the compensation drain electrode of the compensation thin-film transistor T3. An emission control drain electrode of the emission control thin-film transistor T6 may be electrically connected to a second initialization drain electrode of the second initialization thin-film transistor T7 and the pixel electrode of the display element DPE.

The operation control thin-film transistor T5 and the emission control thin-film transistor T6 may be simultaneously turned on according to the emission control signal En received through the emission control line EL, so that the first power supply voltage ELVDD is transmitted to the display element DPE and driving current flows through an organic light-emitting diode OLED. A second power supply voltage ELVSS may be transmitted to the display element DPE.

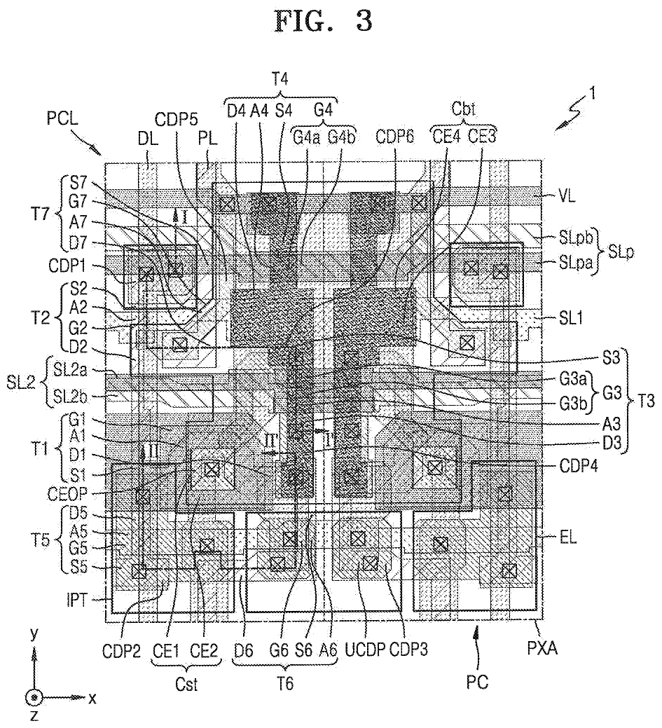

A second initialization gate electrode G7 (FIG. 3) of the second initialization thin-film transistor T7 may be electrically connected to the next scan line SLn. The second initialization source electrode of the second initialization thin-film transistor T7 may be electrically connected to the emission control drain electrode of the emission control thin-film transistor T6 and the pixel electrode of the organic light-emitting diode OLED. The second initialization drain electrode of the second initialization thin-film transistor T7 may be electrically connected to the first initialization source electrode of the first initialization thin-film transistor T4 and the initialization voltage line VL. The second initialization thin-film transistor T7 may be turned on according to the next scan signal Sn+1 received through the next scan line SLn, and may initialize the pixel electrode of the display element DPE.

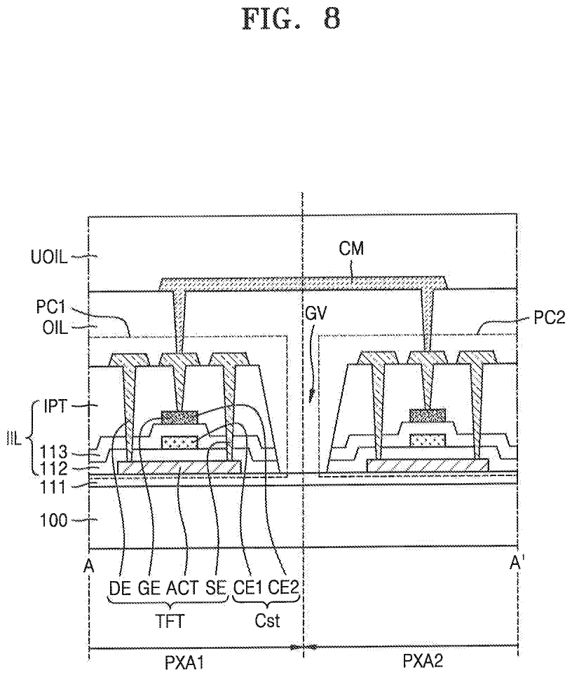

The second initialization thin-film transistor T7 may be connected to the next scan line SLn as shown in FIG. 8. However, embodiments of the present disclosure are not necessarily limited thereto. For example, in an embodiment, the second initialization thin-film transistor T7 may be connected to the emission control line EL and may be driven according to the emission control signal En. Positions of source electrodes and drain electrodes of FIG. 8 may be changed according to a type (a p-type or an n-type) of a transistor.

The storage capacitor Cst may include the first electrode CE1 and a second electrode CE2. The first electrode CE1 of the storage capacitor Cst may be electrically connected to the driving gate electrode of the driving thin-film transistor T1, and the second electrode CE2 of the storage capacitor Cst may be electrically connected to the driving voltage line PL. The storage capacitor Cst may store a charge corresponding to a difference between a driving gate electrode voltage of the driving thin-film transistor T1 and the first power supply voltage ELVDD.

The boost capacitor Cbt may include a third electrode CE3 and a fourth electrode CE4. The third electrode CE3 may be electrically connected to the switching gate electrode of the switching thin-film transistor T2 and the first scan line SL1, and the fourth electrode CE4 may be electrically connected to the compensation source electrode of the compensation thin-film transistor T3 and a node connection line. The boost capacitor Cbt may increase a voltage of a first node N1 when a first scan signal Sn′ provided to the first scan line SL1 is turned off. As such, when a voltage of the first node N1 is increased, a black gray scale may be clearly expressed.

The first node N1 may be an area where the driving gate electrode of the driving thin-film transistor T1, the source electrode of the compensation thin-film transistor T3, the drain electrode of the first initialization thin-film transistor T4, and the fourth electrode CE4 of the boost capacitor Cbt are electrically connected to the node connection line.

In an embodiment, at least one of the plurality of thin-film transistors (e.g., T1 through T7) may include a semiconductor layer including oxide, and a remaining portion of the plurality of thin-film transistors may include a semiconductor layer including silicon.

For example, since the driving thin-film transistor that directly affects the brightness of a display apparatus may include a semiconductor layer formed of polycrystalline silicon having high reliability, a high-resolution display apparatus may be realized.

Since an oxide semiconductor has a high carrier mobility and a small leakage current, voltage drop may not be large even when a driving time is long. For example, because a color change in an image due to voltage drop is not large even during low-frequency driving, low-frequency driving may be possible.

As such, because an oxide semiconductor has small leakage current, when at least one of the compensation thin-film transistor T3, the first initialization thin-film transistor T4, and the second initialization thin-film transistor T7 connected to the driving gate electrode of the driving thin-film transistor T1 includes an oxide semiconductor, leakage current that may flow to the driving gate electrode may be prevented and power consumption may be reduced.

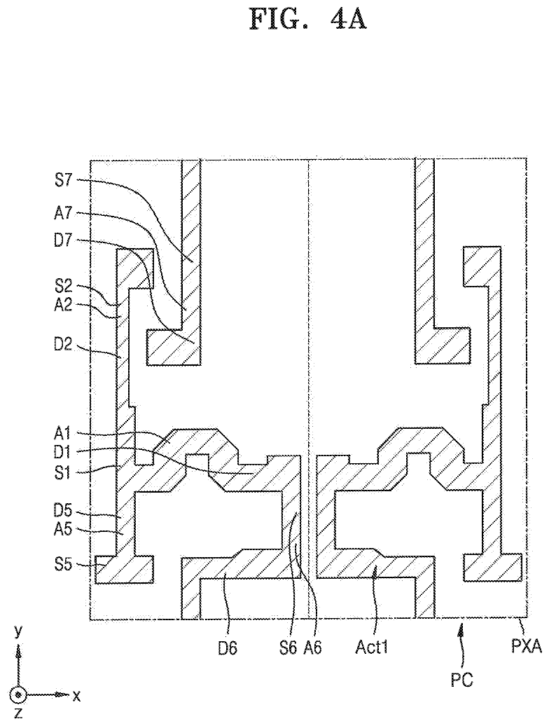

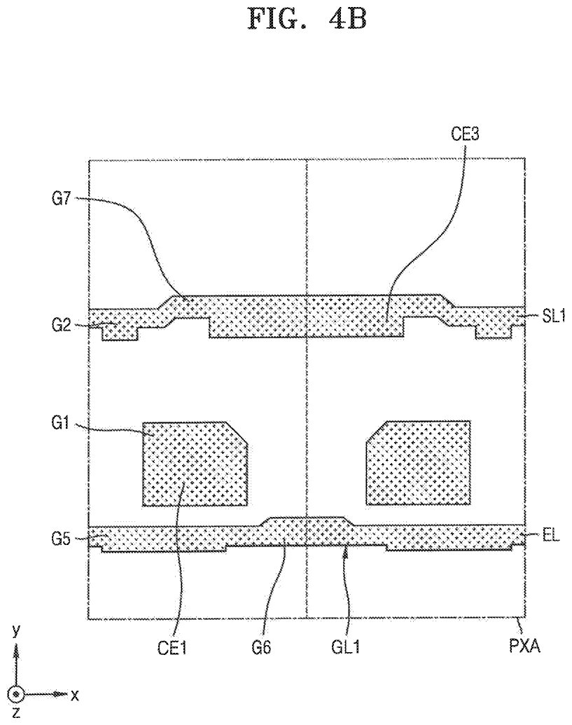

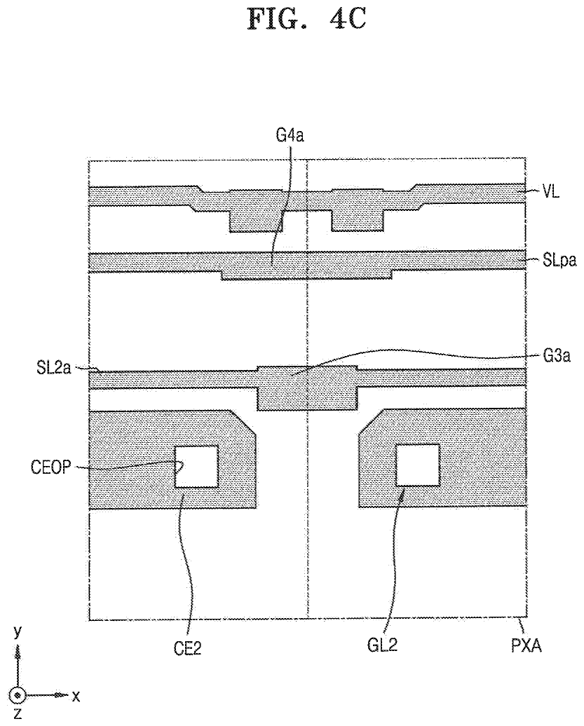

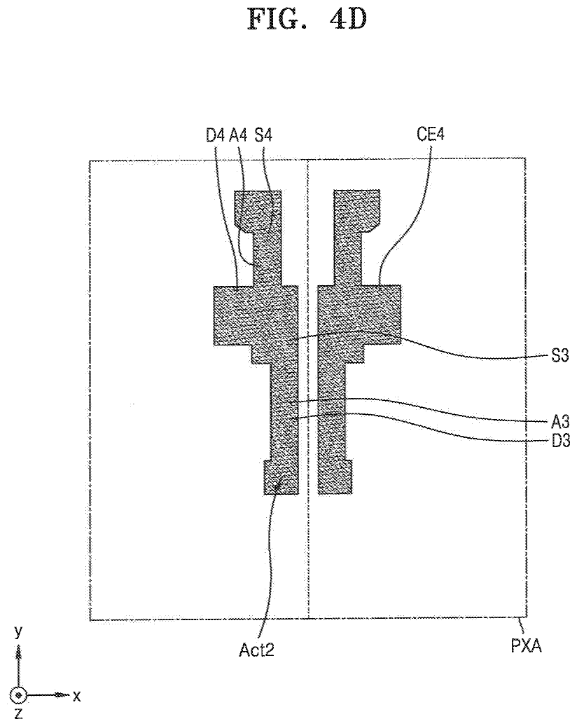

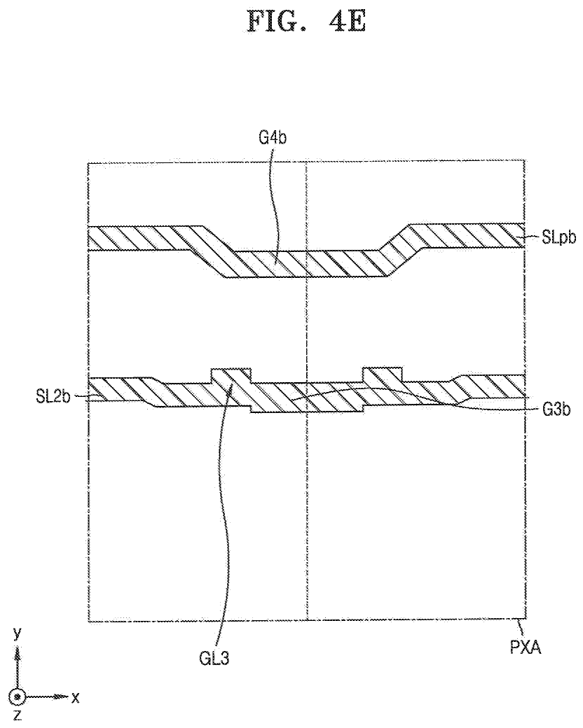

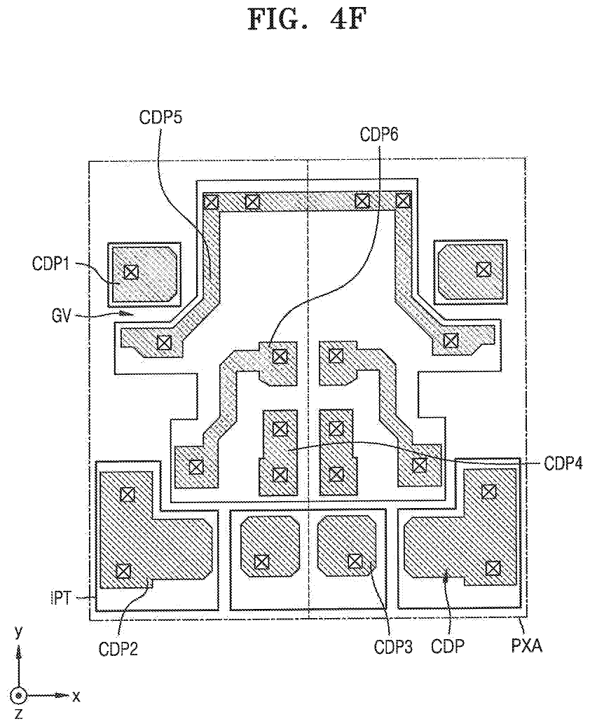

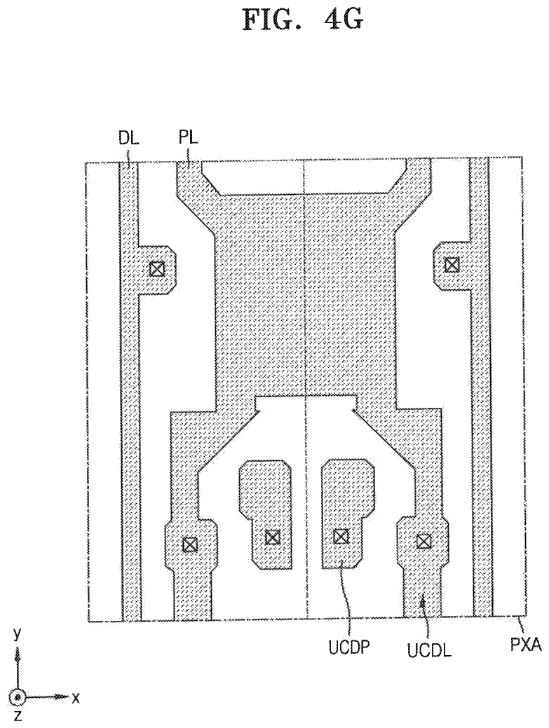

FIG. 3 is a plan view illustrating the sub-pixel area PXA and a pixel circuit layer PCL of the display apparatus 1, according to an embodiment. FIGS. 4A through 4G are plan views partially illustrating elements of FIG. 3. FIG. 4A is a plan view schematically illustrating a first semiconductor layer Act1. FIG. 4B is a plan view schematically illustrating a first gate conductive layer GL1. FIG. 4C is a plan view schematically illustrating a second gate conductive layer GL2. FIG. 4D is a plan view schematically illustrating a second semiconductor layer Act2. FIG. 4E is a plan view schematically illustrating a third gate conductive layer GL3. FIG. 4F is a plan view schematically illustrating a plurality of conductive patterns CDP and a plurality of inorganic insulating patterns IPT. FIG. 4G is a plan view schematically illustrating an upper conductive layer UCDL.

Referring to FIG. 3 and FIGS. 4A through 4G, the pixel circuit layer PCL may define the pixel circuit PC overlapping the sub-pixel area PXA. The pixel circuit PC may include at least one thin-film transistor. In an embodiment, the pixel circuit PC may include the driving thin-film transistor T1, the switching thin-film transistor T2, the compensation thin-film transistor T3, the first initialization thin-film transistor T4, the operation control thin-film transistor T5, the emission control thin-film transistor T6, the second initialization thin-film transistor T7, the storage capacitor Cst, and the boost capacitor Cbt. However, embodiments of the present disclosure are not necessarily limited thereto.

The pixel circuit layer PCL may include the first semiconductor layer Act1, the first gate conductive layer GL1, the second gate conductive layer GL2, the second semiconductor layer Act2, the third gate conductive layer GL3, the plurality of inorganic insulating patterns IPT, the plurality of conductive patterns CDP, and the upper conductive layer UCDL. The first semiconductor layer Act1, the first gate conductive layer GL1, the second gate conductive layer GL2, the second semiconductor layer Act2, the third gate conductive layer GL3, the plurality of inorganic insulating patterns IPT, the plurality of conductive patterns CDP, and the upper conductive layer UCDL may overlap the sub-pixel area PXA.

In an embodiment, the driving thin-film transistor T1, the switching thin-film transistor T2, the operation control thin-film transistor T5, the emission control thin-film transistor T6, and the second initialization thin-film transistor T7 may be provided as thin-film transistors including a silicon semiconductor. The compensation thin-film transistor T3 and the first initialization thin-film transistor T4 may be provided as thin-film transistors including an oxide semiconductor. However, embodiments of the present disclosure are not necessarily limited thereto.

At least one thin-film transistor may be located along the first semiconductor layer Act1 including a silicon semiconductor. Some areas of the first semiconductor layer Act1 may correspond to semiconductor areas of the driving thin-film transistor T1, the switching thin-film transistor T2, the operation control thin-film transistor T5, the emission control thin-film transistor T6, and the second initialization thin-film transistor T7. For example, the semiconductor areas of the driving thin-film transistor T1, the switching thin-film transistor T2, the operation control thin-film transistor T5, the emission control thin-film transistor T6, and the second initialization thin-film transistor T7 may be connected to each other and may be curved in any of various shapes.

The first semiconductor layer Act1 may include a channel region, and a source region and a drain region on both sides of the channel region. For example, a source region and a drain region may be doped with impurities, and the impurities may include N-type impurities or P-type impurities. A source region and a drain region may be a source electrode and a drain electrode of a corresponding thin-film transistor. For convenience of explanation, the following will be described assuming that a source electrode and a drain electrode are respectively a source region and a drain region.

The driving thin-film transistor T1 may include a driving channel region A1, a driving source region S1 and a driving drain region D1 on both sides of the driving channel region A1 (e.g., in the x direction), and a driving gate electrode G1 overlapping the driving channel region A1. In an embodiment as shown in FIG. 4A, the driving channel region A1 may have a shape such as an omega shape, to maintain a relatively long channel length in a narrow space. In an embodiment in which a length of the driving channel region A1 is relatively large, a driving range of a gate voltage may be widened and the gradation of light emitted by a display element may be more precisely controlled, thereby increasing display quality.

The switching thin-film transistor T2 may include a switching channel region A2, a switching source region S2 and a switching drain region D2 on both sides of the switching channel region A2 (e.g., in the y direction), and a switching gate electrode G2 overlapping the switching channel region A2. In an embodiment, the switching drain region D2 may be connected to the driving source region S1.

The operation control thin-film transistor T5 may include an operation control channel region A5, an operation control source region S5 and an operation control drain region D5 on both sides of the operation control channel region A5 (e.g., in the y direction), and an operation control gate electrode G5 overlapping the operation control channel region A5. In an embodiment, the operation control drain region D5 may be connected to the driving source region S1. In an embodiment, the operation control drain region D5 may be connected to the switching drain region D2.

The emission control thin-film transistor T6 may include an emission control channel region A6, an emission control source region S6 and an emission control drain region D6 on both sides of the emission control channel region A6, and an emission control gate electrode G6 overlapping the emission control channel region A6. In an embodiment, the emission control source region S6 may be connected to the driving drain region D1.

The second initialization thin-film transistor T7 may include a second initialization channel region A7, a second initialization source region S7 and a second initialization drain region D7 on both sides of the second initialization channel region A7 (e.g., in the y direction), and a second initialization gate electrode G7 overlapping the second initialization channel region A7. In an embodiment, the second initialization source region S7 may be connected to the emission control drain region D6.

The first gate conductive layer GL1 may be located on the first semiconductor layer Act1 with at least one insulating layer therebetween. In an embodiment, the first gate conductive layer GL1 may include the first scan line SL1, the emission control line EL, and the driving gate electrode G1.

The first scan line SL1 may extend in the first direction (e.g., the x direction or the −x direction). Portions of the first scan line SL1 may correspond to the switching gate electrode G2, the second initialization gate electrode G7, and the third electrode CE3 of the boost capacitor Cbt. For example, a portion of the first scan line SL1 overlapping the switching channel region A2 may be the switching gate electrode G2. Also, a portion of the first scan line SL1 overlapping the second initialization channel region A7 may be the second initialization gate electrode G7. A portion of the first scan line SL1 overlapping the second semiconductor layer Act2 may be the third electrode CE3.

The emission control line EL may extend in the first direction (e.g., the x direction or the −x direction). Some portions of the emission control line EL may correspond to the operation control gate electrode G5 and the emission control gate electrode G6. For example, a portion of the emission control line EL overlapping the operation control channel region A5 may be the operation control gate electrode G5. Also, a portion of the emission control line EL overlapping the emission control channel region A6 may be the emission control gate electrode G6.

The driving gate electrode G1 may be connected to the compensation thin-film transistor T3 through a sixth conductive pattern CDP6 described below.

In an embodiment shown in FIG. 4B, the first scan line SL1, the emission control line EL, and the driving gate electrode G1 may be located on the same layer and may include the same material.

The second gate conductive layer GL2 may be located on at least one insulating layer covering the first gate conductive layer GL1. The second gate conductive layer GL2 may include the initialization voltage line VL, a lower previous scan line SLpa, a second lower scan line SL2a, and the second electrode CE2.

In an embodiment, the initialization voltage line VL may extend in the first direction (e.g., the x direction or the −x direction). The initialization voltage line VL may be connected to the first initialization thin-film transistor T4 and the second initialization thin-film transistor T7 through a fifth conductive pattern CDP5 described below. The initialization voltage line VL may have a constant voltage, such as −2 V. However, embodiments of the present disclosure are not necessarily limited thereto and the voltage of the initialization voltage line VL may vary.

In an embodiment, the lower previous scan line SLpa may extend in the first direction (e.g., the x direction or the −x direction). A portion of the lower previous scan line SLpa may correspond to a first initialization lower gate electrode G4a.

In an embodiment, the second lower scan line SL2a may extend in the first direction (e.g., the x direction or the −x direction). A portion of the second lower scan line SL2a may correspond to a first initialization lower compensation gate electrode G3a.

The second electrode CE2 may overlap the driving gate electrode G1, and may constitute the storage capacitor Cst along with the driving gate electrode G1. In an embodiment, the storage capacitor Cst may include the first electrode CE1 and the second electrode CE2, and the first electrode CE1 may be the driving gate electrode G1. For example, the first electrode CE1 may be integrally provided with the driving gate electrode G1. As such, the storage capacitor Cst may overlap the driving thin-film transistor T1. The second electrode CE2 may include an opening portion CEOP having a closed curve shape. In an embodiment, the opening portion CEOP may expose a central portion of the first electrode CE1.

In an embodiment shown in FIG. 4C, the initialization voltage line VL, the lower previous scan line SLpa, the second lower scan line SL2a, and the second electrode CE2 may be located on the same layer and may include the same material.

The second semiconductor layer Act2 may be located on at least one insulating layer covering the second gate conductive layer GL2. At least one thin-film transistor may be located along the second semiconductor layer Act2 and may include an oxide semiconductor. For example, in an embodiment, some portions of the second semiconductor layer Act2 may correspond to semiconductor areas of the compensation thin-film transistor T3 and the first initialization thin-film transistor T4. In an embodiment, the semiconductor areas of the compensation thin-film transistor T3 and the first initialization thin-film transistor T4 may be connected to each other.

The second semiconductor layer Act2 may include a channel region, and a source region and a drain region on both sides of the channel region. For example, a source region and a drain region may be regions having a high carrier concentration due to plasma treatment. A source region and a drain region may respectively correspond to a source electrode and a drain electrode. Hereinafter, the terms “source region” and “drain region” are used instead of the terms “source electrode” and “drain electrode”.

The compensation thin-film transistor T3 may include a compensation channel region A3, a compensation source region S3 and a compensation drain region D3 on both sides of the compensation channel region A3 (e.g., in the y direction), and a compensation gate electrode G3 overlapping the compensation channel region A3. The compensation source region S3 may be electrically connected to the driving gate electrode G1 through a second conductive pattern CDP2 described below. The compensation source region S3 may be connected to the fourth electrode CE4 of the boost capacitor Cbt. In an embodiment, the compensation source region S3 may be integrally provided with the fourth electrode CE4 of the boost capacitor Cbt. For example, the boost capacitor Cbt may include the third electrode CE3 and the fourth electrode CE4. When the first scan signal Sn′ provided to the first scan line SL1 is turned off, the boost capacitor Cbt may increase a voltage of the sixth conductive pattern CDP6. As such, when a voltage of the sixth conductive pattern CDP6 is increased, a black gray scale may be clearly expressed. The compensation drain region D3 may be electrically connected to the emission control source region S6 through a fourth conductive pattern CDP4 described below.

The first initialization thin-film transistor T4 may include a first initialization channel region A4, a first initialization source region S4 and a first initialization drain region D4 on both sides of the first initialization channel region A4 (e.g., in the y direction), and a first initialization gate electrode G4 overlapping the first initialization channel region A4. In an embodiment, the first initialization drain region D4 may be connected to the compensation source region S3. The first initialization source region S4 may be connected to the fifth conductive pattern CDP5 described below. Accordingly, the first initialization source region S4 may be electrically connected to the initialization voltage line VL.

The third gate conductive layer GL3 may be located on the second semiconductor layer Act2 with at least one insulating layer therebetween. The third gate conductive layer GL3 may include an upper previous scan line SLpb and a second upper scan line SL2b.

The upper previous scan line SLpb may extend in the first direction (e.g., the x direction or the −x direction). The upper previous scan line SLpb may constitute the previous scan line SLp along with the lower previous scan line SLpa. For example, the previous scan line SLp may include the lower previous scan line SLpa and the upper previous scan line SLpb. However, embodiments of the present disclosure are not necessarily limited thereto. For example, in some embodiments, any one of the lower previous scan line SLpa and the upper previous scan line SLpb may be omitted in the configuration for the previous scan line SLp.

A portion of the upper previous scan line SLpb may correspond to a first initialization upper gate electrode G4b. The first initialization upper gate electrode G4b may constitute the first initialization gate electrode G4 along with the first initialization lower gate electrode G4a. For example, the first initialization gate electrode G4 may include the first initialization lower gate electrode G4a and the first initialization upper gate electrode G4b. In this embodiment, the first initialization thin-film transistor T4 may have a double gate structure. In some embodiments, any one of the first initialization lower gate electrode G4a and the first initialization upper gate electrode G4b may be omitted in the configuration for the first initialization gate electrode G4. In this embodiment, the first initialization thin-film transistor T4 may have a single gate structure.

The second upper scan line SL2b may extend in the first direction (e.g., the x direction or the −x direction). The second upper scan line SL2b may constitute the second scan line SL2 along with the second lower scan line SL2a. For example, the second scan line SL2 may include the second lower scan line SL2a and the second upper scan line SL2b. In some embodiments, any one of the second lower scan line SL2a and the second upper scan line SL2b may be omitted in the configuration for the second scan line SL2.

A portion of the second upper scan line SL2b may correspond to an upper compensation gate electrode G3b. The upper compensation gate electrode G3b may constitute the compensation gate electrode G3 along with the lower compensation gate electrode G3a. For example, the compensation gate electrode G3 may include the lower compensation gate electrode G3a and the upper compensation gate electrode G3b. In this embodiment, the compensation thin-film transistor T3 may have a double gate structure. In some embodiments, at least one of the lower compensation gate electrode G3a and the upper compensation gate electrode G3b may be omitted for the configuration of the compensation gate electrode G3. In this embodiment, the compensation thin-film transistor T3 may have a single gate structure.

The plurality of inorganic insulating patterns IPT may be located on the third gate conductive layer GL3, and the plurality of conductive patterns CDP may be located on the plurality of inorganic insulating patterns IPT.

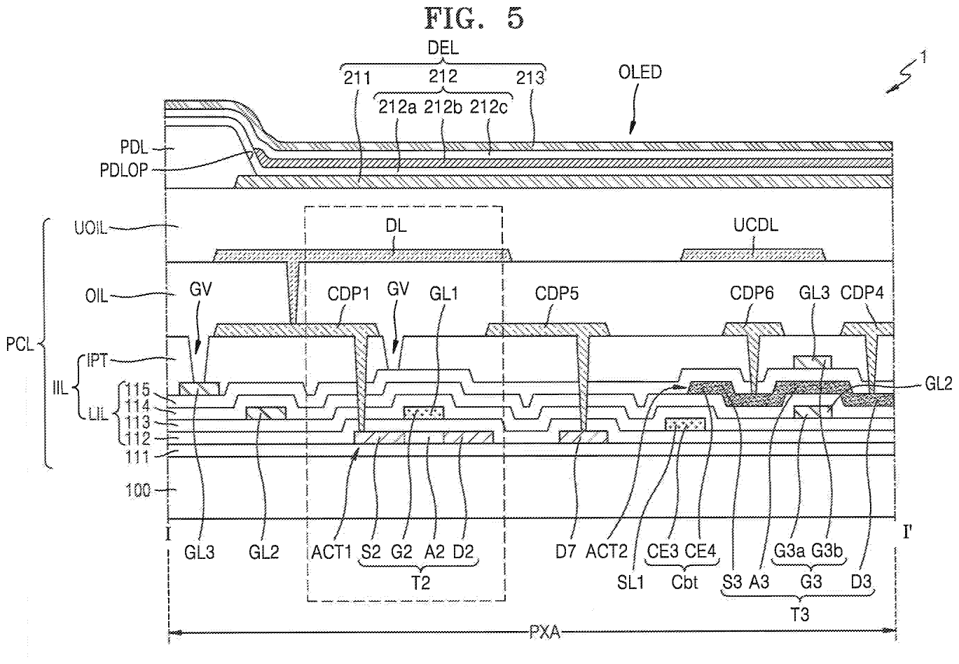

The plurality of inorganic insulating patterns IPT may be located in the sub-pixel area PXA. For example, the plurality of inorganic insulating patterns IPT may overlap the sub-pixel area PXA. In an embodiment, each of the plurality of inorganic insulating patterns IPT may overlap one sub-pixel area PXA. The plurality of inorganic insulating patterns IPT may be spaced apart from each other by a groove GV included in an inorganic insulating layer IIL (see FIG. 5). In an embodiment, the plurality of inorganic insulating patterns IPT may be spaced apart from each other in the sub-pixel area PXA.

A first wiring may overlap any one of the plurality of inorganic insulating patterns IPT, and a second wiring may overlap another one of the plurality of inorganic insulating patterns IPT. The first wiring and the second wiring may overlap the sub-pixel area PXA and may extend in the first direction (e.g., the x direction or the −x direction). For example, in an embodiment the first wiring may be at least one of the first scan line SL1, the second scan line SL2, the previous scan line SLp, and the initialization voltage line VL, and the second wiring may be the emission control line EL.

The plurality of conductive patterns CDP may be located on the plurality of inorganic insulating patterns IPT. In an embodiment, the plurality of conductive patterns CDP may be located on any one of the plurality of inorganic insulating patterns IPT. In other words, the plurality of conductive patterns CDP may be located on one inorganic insulating pattern IPT. However, embodiments of the present disclosure are not necessarily limited thereto. For example, in an embodiment, the plurality of conductive patterns CDP may be respectively located on the plurality of inorganic insulating patterns IPT.

In an embodiment, the plurality of conductive patterns CDP may include a first conductive pattern CDP1, a second conductive pattern CDP2, a third conductive pattern CDP3, a fourth conductive pattern CDP4, a fifth conductive pattern CDP5, and a sixth conductive pattern CDP6.

In an embodiment, the groove GV of the inorganic insulating layer IIL may be located between the first conductive pattern CDP1 and the plurality of conductive patterns CDP spaced apart from the first conductive pattern CDP1. For example, the first conductive pattern CDP1 may be surrounded by the groove GV and the groove GV may be located between the first conductive pattern CDP1 and adjacent conductive patterns of the plurality of conductive patterns CDP. In an embodiment, the groove GV may be comprised of a plurality of grooves.

In an embodiment, the first conductive pattern CDP1 may be located on any one of the plurality of inorganic insulating patterns IPT. The second conductive pattern CDP2 may be located on another one of the plurality of inorganic insulating patterns IPT. The third conductive pattern CDP3 may be located on another one of the plurality of inorganic insulating patterns IPT. For example, the first conductive pattern CDP1, the second conductive pattern CDP2, and the third conductive pattern CDP3 may each be surrounded by the groove GV of the inorganic insulating layer IIL.

However, embodiments of the present disclosure are not necessarily limited thereto. For example, in an embodiment, the second conductive pattern CDP2 and the third conductive pattern CDP3 may be located together on any one of the plurality of inorganic insulating patterns IPT. In this embodiment, the second conductive pattern CDP2 and the third conductive pattern CDP3 may be surrounded together by the groove GV of the inorganic insulating layer IIL.

In an embodiment, the first conductive pattern CDP1 may electrically connect the switching source region S2 to the data line DL. The second conductive pattern CDP2 may electrically connect the driving voltage line PL to the operation control source region S5. The second conductive pattern CDP2 may electrically connect the driving voltage line PL to the second electrode CE2. The third conductive pattern CDP3 may electrically connect the emission control drain region D6 to an upper conductive pattern UCDP described below. The fourth conductive pattern CDP4 may electrically connect the compensation drain region D3 to the emission control source region S6. The fifth conductive pattern CDP5 may electrically connect the first initialization source region S4 to the initialization voltage line VL. The fifth conductive pattern CDP5 may electrically connect the second initialization drain region D7 to the initialization voltage line VL. The sixth conductive pattern CDP6 may electrically connect the driving gate electrode G1 to the compensation source region S3. In an embodiment, the sixth conductive pattern CDP6 may electrically connect the driving gate electrode G1 to the compensation source region S3 through the opening portion CEOP of the second electrode CE2.

In an embodiment, the plurality of conductive patterns CDP may be located on the same layer and may include the same material.

The upper conductive layer UCDL may be located on at least one insulating layer covering the plurality of conductive patterns CDP and the plurality of inorganic insulating patterns IPT. The upper conductive layer UCDL may include the driving voltage line PL, the data line DL, and the upper conductive pattern UCDP. In an embodiment, at least one of the driving voltage line PL and the data line DL may be a third wiring overlapping the sub-pixel area PXA and extending in the second direction (e.g., the y direction or the −y direction).

The driving voltage line PL may extend in the second direction (e.g., the y direction or the −y direction) intersecting the first direction (e.g., the x direction or the −x direction). In an embodiment, the driving voltage line PL may extend substantially in the second direction (e.g., the y direction or the −y direction). The driving voltage line PL may be electrically connected to the second electrode CE2 and the operation control source region S5 through the second conductive pattern CDP2.

The data line DL may extend in the second direction (e.g., the y direction or the −y direction). The data line DL may be electrically connected to the switching source region S2 through the first conductive pattern CDP1. A part of the data line DL may be a switching source electrode.

The upper conductive pattern UCDP may be electrically connected to the third conductive pattern CDP3. In an embodiment, the upper conductive pattern UCDP may be electrically connected to an organic light-emitting diode as a display element.

In an embodiment, the driving voltage line PL, the data line DL, and the upper conductive pattern UCDP may be located on the same layer and may include the same material.

The pixel electrode layer PCL may include the plurality of inorganic insulating patterns IPT spaced apart from each other, and may include the first wiring and the second wiring extending in the first direction (e.g., the x direction or the −x direction) and the third wiring extending in the second direction (e.g., the y direction or the −y direction). For example, the display apparatus 1 may include the plurality of inorganic insulating patterns IPT, and the wirings may be arranged in various ways without being disconnected in the first direction (e.g., the x direction or the −x direction) and/or the second direction (e.g., the y direction or the −y direction). Accordingly, since the display apparatus 1 according to an embodiment includes the plurality of inorganic insulating patterns IPT that are spaced apart from each other, defects due to external impact may be prevented or reduced, and wirings may be arranged in various ways on the pixel circuit layer PCL.

FIG. 5 is a cross-sectional view schematically illustrating the display apparatus taken along line I-I′ of FIG. 3. In FIG. 5, the same elements as those illustrated in FIG. 3 are denoted by the same reference numerals, and thus, a repeated description thereof will be omitted for economy of description.

Referring to FIG. 5, the display apparatus 1 may include the substrate 100, the pixel circuit layer PCL, and a display element layer DEL. The pixel circuit layer PCL may define the pixel circuit PC. For example, the pixel circuit layer PCL may include the pixel circuit PC. In an embodiment as shown in FIG. 5, the display element layer DEL may include an organic light-emitting diode OLED as a display element.

The substrate 100 may include the sub-pixel area PXA. In an embodiment, the substrate 100 may include a plurality of sub-pixel areas PXA. In an embodiment, one pixel circuit PC may be located in the sub-pixel area PXA. In an embodiment, one organic light-emitting diode OLED may be located in the sub-pixel area PXA.

The pixel circuit layer PCL defining the pixel circuit PC may be located on the substrate 100. The pixel circuit PC may overlap the sub-pixel area PXA. In an embodiment, the pixel circuit layer PCL may include a buffer layer 111, the first semiconductor layer Act1, the first gate conductive layer GL1, the second gate conductive layer GL2, the second semiconductor layer Act2, the third gate conductive layer GL3, the inorganic insulating layer IIL, the plurality of conductive patterns CDP, an organic insulating layer OIL, the upper conductive pattern UCDP, and an upper organic insulating layer UOIL.

The inorganic insulating layer IIL may include the groove GV. The inorganic insulating layer IIL may include the plurality of inorganic insulating patterns IPT spaced apart from each other by the groove GV and a lower inorganic insulating layer LIL located between the substrate 100 and the plurality of inorganic insulating patterns IPT.

The first semiconductor layer Act1 may be located on the buffer layer 111. In an embodiment, the first semiconductor layer Act1 may include a silicon semiconductor. In an embodiment, the first semiconductor layer Act1 may include the switching source region S2, the switching channel region A2, and the switching drain region D2 of the switching thin-film transistor T2.

The lower inorganic insulating layer LIL may be located on the substrate 100. In an embodiment, the lower inorganic insulating layer LIL may be located between the substrate 100 and the plurality of inorganic insulating patterns IPT. In an embodiment, the lower inorganic insulating layer LIL may be continuously located on the substrate 100. In an embodiment, the lower inorganic insulating layer LIL may include a first gate insulating layer 112, a second gate insulating layer 113, a lower insulating layer 114, and a third gate insulating layer 115 sequentially disposed on the substrate 100. The lower inorganic insulating layer LIL may include at least one insulating layer located between the first semiconductor layer Act1 and the plurality of inorganic insulating patterns IPT. For example, the first semiconductor layer Act1 may be located between the substrate 100 and the first gate insulating layer 112.

The first gate conductive layer GL1 may be located on (e.g., disposed directly thereon) the first gate insulating layer 112. In an embodiment, the first gate conductive layer GL1 may be located between the first gate insulating layer 112 and the second gate insulating layer 113. In an embodiment, the first gate conductive layer GL1 may include the first scan line SL1 and the emission control line EL. The first scan line SL1 may extend in the first direction (e.g., in FIG. 9, the x direction or the −x direction). The first scan line SL overlapping the switching channel region A2 may be the switching gate electrode G2. The second gate insulating layer 113 may cover the first gate conductive layer GL1.

The second gate conductive layer GL2 may be located on (e.g., disposed directly thereon) the second gate insulating layer 113. In an embodiment, the second gate conductive layer GL2 may include the lower compensation gate electrode G3a.

The lower insulating layer 114 may cover the second gate conductive layer GL2.

For example, the second gate conductive layer GL2 may be located between the second gate insulating layer 113 and the lower insulating layer 114. In an embodiment, the lower insulating layer 114 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

The second semiconductor layer Act2 may be located on (e.g., disposed directly thereon) the lower insulating layer 114. In an embodiment, the second semiconductor layer Act2 may include an oxide semiconductor. In an embodiment, the second semiconductor layer Act2 may include the compensation channel region A3, the compensation source region S3, and the compensation drain region D3.

In an embodiment, a portion of the first scan line SL1 may be the third electrode CE3, and a portion of the second semiconductor layer Act2 may be the fourth electrode CE4. The third electrode CE3 and the fourth electrode CE4 may constitute the boost capacitor Cbt.

The lower inorganic insulating layer LIL may include at least one insulating layer located between the second semiconductor layer Act2 and the plurality of inorganic insulating patterns IPT. For example, in an embodiment, the third gate insulating layer 115 may cover the second semiconductor layer Act2. For example, the second semiconductor layer Act2 may be located between the lower insulating layer 114 and the third gate insulating layer 115.

In an embodiment, the third gate insulating layer 115 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

The third gate conductive layer GL3 may be located on (e.g., disposed directly thereon) the third gate insulating layer 115. In an embodiment, the third gate conductive layer GL3 may include the upper compensation gate electrode G3b. The upper compensation gate electrode G3b may constitute the compensation gate electrode G3 along with the lower compensation gate electrode G3a. For example, in an embodiment the compensation gate electrode G3 may include the lower compensation gate electrode G3a and the upper compensation gate electrode G3b. In this embodiment, the compensation thin-film transistor T3 may have a double gate structure. In some embodiments, at least one of the lower compensation gate electrode G3a and the upper compensation gate electrode G3b may be omitted for the configuration of the compensation gate electrode G3. In this embodiment, the compensation thin-film transistor T3 may have a single gate structure.

The inorganic insulating layer IIL may include the lower inorganic insulating layer LIL and the plurality of inorganic insulating patterns IPT. The lower inorganic insulating layer LIL may include the first gate insulating layer 112, the second gate insulating layer 113, the lower insulating layer 114, and the third gate insulating layer 115.

The inorganic insulating layer IIL may include the groove GV. The groove GV may overlap the organic light-emitting diode OLED as a display element. The plurality of inorganic insulating patterns IPT may be spaced apart from each other by the groove GV. The plurality of inorganic insulating patterns IPT may be surrounded by the groove GV. The plurality of inorganic insulating patterns IPT may be located on the lower inorganic insulating layer LIL.

The plurality of inorganic insulating patterns IPT may be located in the sub-pixel area PXA. In an embodiment, the plurality of inorganic insulating patterns IPT may overlap the sub-pixel area PXA. For example, the plurality of inorganic insulating patterns IPT may overlap one sub-pixel area PXA.

In an embodiment, the plurality of conductive patterns CDP may be located on the plurality of inorganic insulating patterns IPT. In an embodiment, the plurality of conductive patterns CDP may include the first conductive pattern CDP1, the fourth conductive pattern CDP4, the fifth conductive pattern CDP5, and the sixth conductive pattern CDP6.

In an embodiment, the groove GV of the inorganic insulating layer IIL may be located between the first conductive pattern CDP1 and the plurality of conductive patterns CDP spaced apart from the first conductive pattern CDP1. For example, only the first conductive pattern CDP1 from among the plurality of conductive patterns CDP may be located on one of the plurality of inorganic insulating patterns IPT.

For example, the first conductive pattern CDP1 may be located on any one of the plurality of inorganic insulating patterns IPT. The fourth conductive pattern CDP4, the fifth conductive pattern CDP5, and the sixth conductive pattern CDP6 may be located on another one of the plurality of inorganic insulating patterns IPT.

The first conductive pattern CDP1 may be electrically connected to the switching source region S2 of the first semiconductor layer Act1 through contact holes extending through the inorganic insulating pattern IPT and the lower inorganic insulating layer LIL. The fourth conductive pattern CDP4 may be electrically connected to the compensation drain region D3 of the second semiconductor layer Act2 through contact holes extending through the inorganic insulating pattern IPT and the lower inorganic insulating layer LIL. The fifth conductive pattern CDP5 may be electrically connected to the first initialization drain region D7 of the first semiconductor layer Act1 through contact holes extending through the inorganic insulating pattern IPT and the lower inorganic insulating layer LIL. The sixth conductive pattern CDP6 may be electrically connected to the compensation source region S3 of the second semiconductor layer Act2 through contact holes extending through the inorganic insulating pattern IPT and the lower inorganic insulating layer LIL.

The organic insulating layer OIL may be located on (e.g., disposed directly thereon) the inorganic insulating layer IIL. The organic insulating layer OIL may fill the groove GV of the inorganic insulating layer IIL. For example, the organic insulating layer OIL may be located between the plurality of inorganic insulating patterns IPT.

The organic insulating layer OIL may cover the plurality of conductive patterns CDP. In an embodiment, the plurality of conductive patterns CDP may be located between the inorganic insulating layer IIL and the organic insulating layer OIL.

In a comparative embodiment, when the inorganic insulating layer IIL is continuously arranged without including the groove GV, the display apparatus 1 may be damaged by an external impact. For example, the plurality of conductive patterns CDP may be damaged by the external impact.

In an embodiment of the present disclosure, since the inorganic insulating layer IIL includes the groove GV, the plurality of conductive patterns CDP may be located on the plurality of inorganic insulating patterns IPT that are spaced apart from each other, thereby preventing damage to the display apparatus 1 due to external impact.

For example, even when a crack occurs in any one of the plurality of inorganic insulating patterns IPT due to an external impact, the crack may not be propagated to another one of the plurality of inorganic insulating patterns IPT. Also, because the plurality of inorganic insulating patterns IPT are spaced apart from each other, strain of the plurality of inorganic insulating patterns IPT may be reduced.

The plurality of inorganic insulating patterns IPT may be spaced apart from each other in the sub-pixel area PXA, and the groove GV of the inorganic insulating layer IIL that separates the plurality of inorganic insulating patterns IPT from each other may overlap the organic light-emitting diode OLED that is a display element. Accordingly, even in an embodiment in which the display apparatus 1 includes the plurality of inorganic insulating patterns IPT, it may not be necessary to increase the area of the sub-pixel area PXA not overlapping the display element and a resolution of the display apparatus 1 may be maintained high.

The upper conductive layer UCDL may be located on (e.g., disposed directly thereon) the organic insulating layer OIL. In an embodiment, the upper conductive layer UCDL may include the data line DL. In an embodiment, the data line DL may be connected to the first conductive pattern CDP1 through a contact hole extending through the organic insulating layer OIL.

The upper organic insulating layer UOIL may cover the upper conductive layer UCDL.

The display element layer DEL may be located on (e.g., disposed directly thereon) the pixel circuit layer PCL. The display element layer DEL may include the organic light-emitting diode OLED as a display element electrically connected to the pixel circuit PC. In an embodiment, the organic light-emitting diode OLED may include a pixel electrode 211, an intermediate layer 212, and a counter electrode 213.

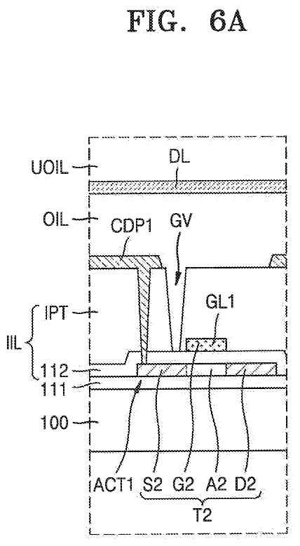

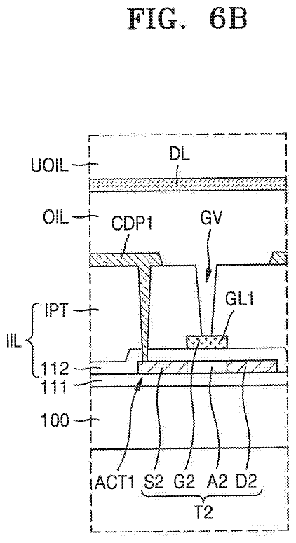

FIGS. 6A and 6B are each a cross-sectional view illustrating a portion marked by a dashed line of FIG. 5. In FIGS. 6A and 68, the same elements as those illustrated in FIG. 5 are denoted by the same reference numerals, and thus, a repeated description thereof will be omitted for economy of description.

Referring to FIG. 6A, the display apparatus 1 may include the substrate 100, the buffer layer 111, the first semiconductor layer Act1, the first gate conductive layer GL1, the inorganic insulating layer IIL, the first conductive pattern CDP1, the organic insulating layer OIL, the data line DL, and the upper organic insulating layer UOIL.

The inorganic insulating layer IIL may include the groove GV. The inorganic insulating layer IIL may include the lower inorganic insulating layer LIL and the plurality of inorganic insulating patterns IPT spaced apart from each other by the groove GV. In an embodiment, the groove GV may be located between the first conductive pattern CDP1 and the plurality of conductive patterns CDP spaced apart from the first conductive pattern CDP1.

The lower inorganic insulating layer LIL may include at least one insulating layer between the first semiconductor layer Act1 and the inorganic insulating pattern IPT. In an embodiment, the lower inorganic insulating layer LIL may include the first gate insulating layer 112 disposed between the first semiconductor layer Act1 and the inorganic insulating pattern IPT. In this embodiment, the groove GV of the inorganic insulating layer IIL may expose a portion of the first gate insulating layer 112. However, embodiments of the present disclosure are not necessarily limited thereto. For example, in an embodiment, the lower inorganic insulating layer LIL may include the first gate insulating layer 112, the second gate insulating layer 113, the lower insulating layer 114, and a third gate insulating layer.

Referring to FIG. 6B, the display apparatus 1 may include the substrate 100, the buffer layer 111, the first semiconductor layer Act1, the first gate conductive layer GL1, the inorganic insulating layer IIL, the first conductive pattern CDP1, the organic insulating layer OIL, the data line DL, and the upper organic insulating layer UOIL.

The inorganic insulating layer IIL may include the groove GV. The inorganic insulating layer IIL may include the lower inorganic insulating layer LIL and the plurality of inorganic insulating patterns IPT spaced apart from each other by the groove GV.

The groove GV may be located between the first conductive pattern CDP1 and the plurality of conductive patterns CDP spaced apart from the first conductive pattern CDP1. In an embodiment as shown in FIG. 6B, the groove GV of the inorganic insulating layer IIL may expose at least a portion of the first gate conductive layer GL1 instead of a portion of the first gate insulating layer 112 as shown in an embodiment of FIG. 6A.

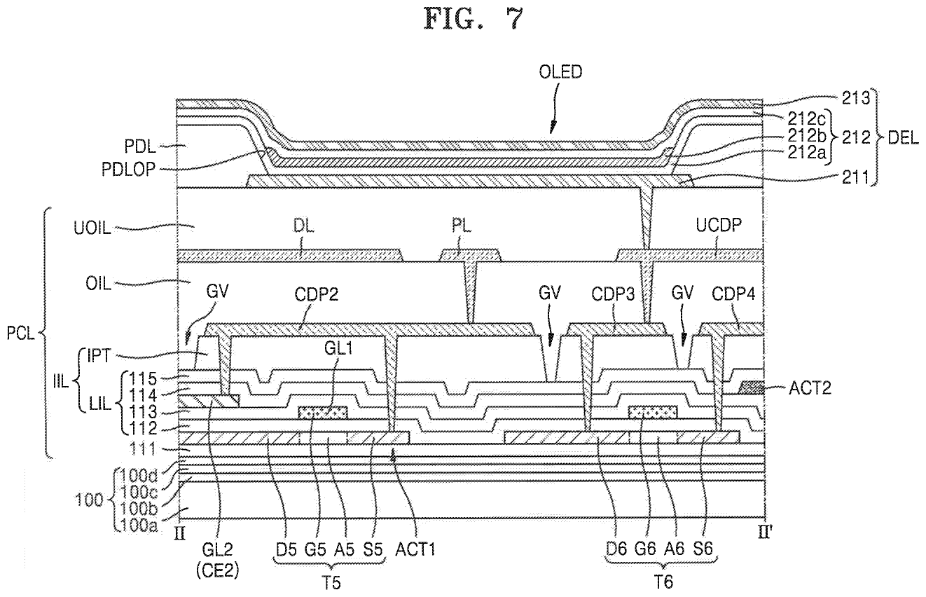

FIG. 7 is a cross-sectional view schematically illustrating the display apparatus taken along line II-II′ of FIG. 3.

Referring to FIG. 7, the display apparatus 1 may include the substrate 100, the pixel circuit layer PCL, and the display element layer DEL. The pixel circuit layer PCL may define the pixel circuit PC. For example, the pixel circuit layer PCL may include the pixel circuit PC. In an embodiment, the display element layer DEL may include an organic light-emitting diode OLED as a display element. However, embodiments of the present disclosure are not necessarily limited thereto.

The substrate 100 may include the sub-pixel area PXA. In an embodiment, the substrate 100 may include a plurality of sub-pixel areas PXA. In an embodiment, one pixel circuit PC may be located in the sub-pixel area PXA. In an embodiment, one organic light-emitting diode OLED may be located in the sub-pixel area PXA.

In an embodiment, the substrate 100 may include a first base layer 100a, a first barrier layer 100b, a second base layer 100c, and a second barrier layer 100d. In an embodiment, the first base layer 100a, the first barrier layer 100b, the second base layer 100c, and the second barrier layer 100d may be sequentially stacked on the substrate 100. However, embodiments of the present disclosure are not necessarily limited thereto. For example, in an embodiment, the substrate 100 may include glass.

In an embodiment, at least one of the first base layer 100a and the second base layer 100c may include a polymer resin such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

In an embodiment, each of the first barrier layer 100b and the second barrier layer 100d which is a barrier layer for preventing penetration of an external foreign material may have a single or multi-layer structure including an inorganic material such as silicon nitride (SiNₓ), silicon oxide (SiO₂), and/or silicon oxynitride (SiON).

The pixel circuit layer PCL defining the pixel circuit PC may be located on (e.g., disposed directly thereon) the substrate 100. The pixel circuit PC may overlap the sub-pixel area PXA. The pixel circuit layer PCL may include the buffer layer 111, the first semiconductor layer Act1, the first gate conductive layer GL1, the second gate conductive layer GL2, the second semiconductor layer Act2, the third gate conductive layer GL3, the inorganic insulating layer IIL, the plurality of conductive patterns CDP, the organic insulating layer OIL, the upper conductive layer UCDL, and the upper organic insulating layer UOIL. The inorganic insulating layer IIL may include the lower inorganic insulating layer LIL and the plurality of inorganic insulating patterns IPT. The inorganic insulating layer IIL may include the groove GV.

The first semiconductor layer Act1 may be located on (e.g., disposed directly thereon) the buffer layer 111. In an embodiment, the first semiconductor layer Act1 may include a silicon oxide. In an embodiment, the first semiconductor layer Act1 may include the operation control source region S5, the operation control channel region A5, and the operation control drain region D5 of the operation control thin-film transistor T5. In an embodiment, the first semiconductor layer Act1 may include the emission control source region S6, the emission control channel region A6, and the emission control drain region D6 of the emission control thin-film transistor T6.

The lower inorganic insulating layer LIL may be located on the substrate 100. In an embodiment, the lower inorganic insulating layer LIL may be located between the substrate 100 and the plurality of inorganic insulating patterns IPT. In an embodiment, the lower inorganic insulating layer LIL may be continuously located on the substrate 100. In an embodiment, a portion of a top surface of the lower inorganic insulating layer LIL may be exposed through the groove GV of the inorganic insulating layer IIL. The lower inorganic insulating layer LIL may include the first gate insulating layer 112, the second gate insulating layer 113, the lower insulating layer 114, and the third gate insulating layer 115 which are sequentially located on (e.g., stacked on) the substrate 100.

The first gate conductive layer GL1 may be located on (e.g., disposed directly thereon) the first gate insulating layer 112. In an embodiment, the first gate conductive layer GL1 may be located between the first gate insulating layer 112 and the second gate insulating layer 113. In an embodiment, the first gate conductive layer GL1 may include the first scan line SL1 and the emission control line EL. The first scan line SL1 may extend in the first direction (e.g., in FIG. 4B, the x direction or the −x direction). The emission control line EL may extend in the first direction (e.g., in FIG. 4B, the x direction or the −x direction). The emission control line EL may overlap the emission control channel region A6. The emission control line EL overlapping the emission control channel region A6 may be the emission control gate electrode G6. The second gate insulating layer 113 may cover the first gate conductive layer GL1.

The second gate conductive layer GL2 may be located on (e.g., disposed directly thereon) the second gate insulating layer 113. In an embodiment, the second gate conductive layer GL2 may include the second electrode CE2 of the storage capacitor Cst.

The lower insulating layer 114 may cover the second gate conductive layer GL2. For example, the second gate conductive layer GL2 may be located between the second gate insulating layer 113 and the lower insulating layer 114. In an embodiment, the lower insulating layer 114 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

The second semiconductor layer Act2 may be located on (e.g., disposed directly thereon) the lower insulating layer 114. In an embodiment, the second semiconductor layer Act2 may include an oxide semiconductor.

The third gate insulating layer 115 may cover the second semiconductor layer Act2. For example, the second semiconductor layer Act2 may be located between the lower insulating layer 114 and the third gate insulating layer 115. In an embodiment, the third gate insulating layer 115 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO). The third gate conductive layer GL3 may be located on the third gate insulating layer 115.

The inorganic insulating layer IIL may include the groove GV. The inorganic insulating layer IIL may include the lower inorganic insulating layer LIL and the plurality of inorganic insulating patterns IPT spaced apart from each other by the groove GV.

The lower inorganic insulating layer LIL may be located on the substrate 100. In an embodiment, the lower inorganic insulating layer LIL may be continuously located between the substrate 100 and the plurality of inorganic insulating patterns IPT. The lower inorganic insulating layer LIL may include the first gate insulating layer 112, the second gate insulating layer 113, the lower insulating layer 114, and the third gate insulating layer 115 which are sequentially located on the substrate 100.

The plurality of inorganic insulating patterns IPT may be located in the sub-pixel area PXA. For example, the plurality of inorganic insulating patterns IPT may overlap the sub-pixel area PXA. In an embodiment, the plurality of inorganic insulating patterns IPT may overlap one sub-pixel area PXA.

The plurality of inorganic insulating patterns IPT may be located on (e.g., disposed directly thereon) the lower inorganic insulating layer LIL. The plurality of inorganic insulating patterns IPT may be surrounded by the groove GV. The plurality of inorganic insulating patterns IPT may be spaced apart from each other by the groove GV of the inorganic insulating layer IIL. In an embodiment, the plurality of inorganic insulating patterns IPT may be spaced apart from each other in the sub-pixel area PXA. The groove GV may be located in the sub-pixel area PXA, and may overlap the organic light-emitting diode OLED as a display element,

The plurality of conductive patterns CDP may be located on (e.g., disposed directly thereon) the plurality of inorganic insulating patterns IPT. In an embodiment, the plurality of conductive patterns CDP may include the second conductive pattern CDP2, the third conductive pattern CDP3, and the fourth conductive pattern CDP4.

In an embodiment, each of the plurality of conductive patterns CDP may be surrounded by the groove GV of the inorganic insulating layer IIL. The groove GV of the inorganic insulating layer IIL may be located between the plurality of conductive patterns CDP that are spaced apart from each other.

In an embodiment, the plurality of conductive patterns CDP may be respectively located on the plurality of inorganic insulating patterns IPT. For example, the second conductive pattern CDP2 may be located on any one of the plurality of inorganic insulating patterns IPT. The third conductive pattern CDP3 may be located on another one of the plurality of inorganic insulating patterns IPT. The fourth conductive pattern CDP4 may be located on another one of the plurality of inorganic insulating patterns IPT.

The second conductive pattern CDP2 may be electrically connected to the operation control source region S5 of the first semiconductor layer Act1 through contact holes extending through the inorganic insulating pattern IPT and the lower inorganic insulating layer LIL. The third conductive pattern CDP3 may be electrically connected to the emission control drain region D6 of the first semiconductor layer Act1 through contact holes extending through the inorganic insulating pattern IPT and the lower inorganic insulating layer LIL. The fourth conductive pattern CDP4 may be electrically connected to the emission control source region S6 of the first semiconductor layer Act1 through contact holes extending through the inorganic insulating pattern IPT and the lower inorganic insulating layer LIL.

The organic insulating layer OIL may be located on (e.g., disposed directly thereon) the inorganic insulating layer IIL. The organic insulating layer OIL may fill the groove GV of the inorganic insulating layer IIL. For example, the organic insulating layer OIL may be located between the plurality of inorganic insulating patterns IPT.

The organic insulating layer OIL may cover the plurality of conductive patterns CDP. In an embodiment, the plurality of conductive patterns CDP may be located between the inorganic insulating layer IIL and the organic insulating layer OIL.

In a comparative embodiment, when the inorganic insulating layer IIL is continuously located without including the groove GV, the display apparatus 1 may be damaged by an external impact. For example, the plurality of conductive patterns CDP may be damaged by the external impact.

In an embodiment of the present disclosure, since the inorganic insulating layer IIL includes the groove GV, the plurality of conductive patterns CDP may be located on the plurality of inorganic insulating patterns IPT that are spaced apart from each other, thereby preventing the display apparatus 1 from being damaged by an external impact.

For example, even when a crack occurs in any one of the plurality of inorganic insulating patterns IPT due to an external impact, the crack may not be propagated to another one of the plurality of inorganic insulating patterns IPT. Also, because the plurality of inorganic insulating patterns IPT are spaced apart from each other, strain of the plurality of inorganic insulating patterns IPT may be reduced.

The plurality of inorganic insulating patterns IPT may be spaced apart from each other in the sub-pixel area PXA, and the groove GV of the inorganic insulating layer IIL that separates the plurality of inorganic insulating patterns IPT from each other may overlap the organic light-emitting diode OLED as a display element. Accordingly, even when the display apparatus 1 includes the plurality of inorganic insulating patterns IPT, it may not be necessary to increase the area of the sub-pixel area PXA not overlapping the display element and a resolution of the display apparatus 1 may be maintained high.

The upper conductive layer UCDL may be located on (e.g., disposed directly thereon) the organic insulating layer OIL. The upper conductive layer UCDL may include the data line DL, the driving voltage line PL, and the upper conductive pattern UCDP. In an embodiment, the driving voltage line PL may be connected to the second conductive pattern CDP2 through a contact hole extending through the organic insulating layer OIL. The upper conductive pattern UCDP may be connected to the third conductive pattern CDP3 through a contact hole extending through the organic insulating layer OIL.

The upper organic insulating layer UOIL may cover the upper conductive layer UCDL.

The display element layer DEL may be located on (e.g., disposed directly thereon) the pixel circuit layer PCL. The display element layer DEL may include the organic light-emitting diode OLED as a display element electrically connected to the pixel circuit PC. The organic light-emitting diode OLED may include the pixel electrode 211, the intermediate layer 212, and the counter electrode 213. The pixel electrode 211 may be electrically connected to the upper conductive pattern UCDP through a contact hole extending through the upper organic insulating layer UOIL.

FIG. 8 is a cross-sectional view schematically illustrating the display apparatus taken along line A-A′ of FIG. 1. Referring to FIG. 8, the pixel circuit PC located on the substrate 100 and overlapping the sub-pixel area PXA may include a thin-film transistor TFT and a capacitor Cst, and may be connected to signal lines such as a scan line and a data line. In an embodiment, one pixel circuit PC may be located in the sub-pixel area PXA. For example, a first pixel circuit PC1 may be located in a first sub-pixel area PXA1. A second pixel circuit PC2 may be located in a second sub-pixel area PXA2.

The buffer layer 111 may be located on (e.g., disposed directly thereon) the substrate 100. In an embodiment, the buffer layer 111 may include an inorganic insulating material such as silicon nitride (SiNₓ), silicon oxynitride (SiON), and/or silicon oxide (SiO₂), and may have a single or multi-layer structure including the inorganic insulating material.

A semiconductor layer ACT may be located on (e.g., disposed directly thereon) the buffer layer 111. In an embodiment, the semiconductor layer ACT may include amorphous silicon, polycrystalline silicon, oxide, or an organic semiconductor material. The semiconductor layer ACT may include a channel region, a source region, and a drain region. The semiconductor layer ACT may be separated from the semiconductor layer ACT of a neighboring pixel area PCA for each pixel area PCA.

The inorganic insulating layer IIL may be located on (e.g., disposed directly thereon) the buffer layer 111. In an embodiment, the inorganic insulating layer IIL may include the groove GV overlapping the pixel area PCA (see FIGS. 5 and 7). The inorganic insulating layer IIL may include the plurality of inorganic insulating patterns IPT surrounded by the groove GV. The plurality of inorganic insulating patterns IPT may be spaced apart from each other by the groove GV. For example, the first pixel circuit PC1 may include a plurality of inorganic insulating patterns IPT that are spaced apart from each other. The second pixel circuit PC2 may include a plurality of inorganic insulating patterns IPT that are spaced apart from each other.

In an embodiment, the inorganic insulating layer IIL may include the groove GV surrounding each pixel area PCA. The groove GV may expose a portion of the buffer layer 111.

A source electrode SE and a drain electrode DE may be located on the inorganic insulating layer IIL. The source electrode SE and the drain electrode DE may be respectively connected to the source region and the drain region of the semiconductor layer ACT through a contact hole extending through the inorganic insulating layer IIL.

The organic insulating layer OIL may be located on (e.g., disposed directly thereon) the inorganic insulating layer IIL. The organic insulating layer OIL may fill the groove GV of the inorganic insulating layer IIL surrounding each pixel area PCA. Accordingly, stress or a crack caused by bending of a display panel may be prevented from being propagated to another pixel area.

The upper organic insulating layer UOIL may be located on (e.g., disposed directly thereon) the organic insulating layer OIL. A connection electrode CM may be located between the organic insulating layer OIL and the upper organic insulating layer UOIL. The connection electrode CM may connect neighboring pixel circuits PC through contact holes extending through the organic insulating layer OIL. For example, the first pixel circuit PC1 and the second pixel circuit PC2 may be electrically connected to each other by the connection electrode CM.

As described above, a display apparatus according to an embodiment may include a plurality of inorganic insulating patterns overlapping a sub-pixel area and spaced apart from each other and an organic insulating layer covering the plurality of inorganic insulating patterns. Accordingly, defects due to an external impact may be prevented or reduced and a high resolution may be maintained.

It should be understood that embodiments of the present disclosure described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope of the present disclosure.

What is claimed is:

1. A display apparatus comprising:
a substrate comprising a sub-pixel area;
a pixel circuit layer located on the substrate and defining a pixel circuit overlapping the sub-pixel area; and
a display element layer located on the pixel circuit layer and comprising a display element,
wherein the pixel circuit layer comprises:
an inorganic insulating layer located on the substrate and comprising a groove;
an organic insulating layer located on the inorganic insulating layer; and
a plurality of conductive patterns located between the inorganic insulating layer and the organic insulating layer,
wherein the plurality of conductive patterns comprises a first conductive pattern connected to a data line, the data line is located on the organic insulating layer,
wherein the groove is located between the first conductive pattern and adjacent conductive patterns of the plurality of conductive patterns, the adjacent conductive patterns are spaced apart from the first conductive pattern.

2. The display apparatus of claim 1, wherein:
the groove is filled with the organic insulating layer; and
the groove overlaps the display element.

3. The display apparatus of claim 2, wherein:
the inorganic insulating layer comprises a plurality of inorganic insulating patterns spaced apart from each other by the groove; and
a lower inorganic insulating layer located between the substrate and the plurality of inorganic insulating patterns.

4. The display apparatus of claim 3, wherein:
the pixel circuit layer further comprises a first semiconductor layer located on the substrate, the first semiconductor layer comprising a silicon semiconductor,
wherein the lower inorganic insulating layer comprises at least one insulating layer located between the first semiconductor layer and the plurality of inorganic insulating patterns.

5. The display apparatus of claim 4, wherein:
the pixel circuit layer further comprises a second semiconductor layer located on the substrate, the second semiconductor layer comprising an oxide semiconductor,
wherein the lower inorganic insulating layer comprises at least one insulating layer located between the second semiconductor layer and the plurality of inorganic insulating patterns.

6. The display apparatus of claim 3, wherein:
the pixel circuit layer further comprises a semiconductor layer located on the substrate and a gate conductive layer located on the semiconductor layer,
wherein at least a portion of the gate conductive layer is exposed through the groove of the inorganic insulating layer.

7. The display apparatus of claim 2, wherein:
the pixel circuit layer further comprises:
an upper conductive pattern located on the organic insulating layer and connected to the display element; and
an upper organic insulating layer located on the upper conductive pattern; and
the plurality of conductive patterns comprises:
a second conductive pattern connected to a driving voltage line and a third conductive pattern connected to the upper conductive pattern,
wherein the groove is further located between the second conductive pattern and the third conductive pattern.

8. The display apparatus of claim 7, wherein:
the display element layer further comprises a pixel electrode located on the upper organic insulating layer;
the first conductive pattern electrically connects the data line to a switching transistor;
the second conductive pattern electrically connects the driving voltage line to an operation control transistor, and
the third conductive pattern electrically connects the pixel electrode to an emission control transistor.

9. The display apparatus of claim 1, wherein:
the sub-pixel area comprises a first sub-pixel area and a second sub-pixel area each surrounded by the groove of the inorganic insulating layer,
wherein the pixel circuit comprises a first pixel circuit overlapping the first sub-pixel area and a second pixel circuit overlapping the second sub-pixel area,
wherein a connection electrode is located on the organic insulating layer, the connection electrode connecting the first pixel circuit and the second pixel circuit to each other.

10. The display apparatus of claim 8, wherein the display element layer further comprises:
an intermediate layer located on the pixel electrode; and
a counter electrode covering the intermediate layer.

11. A display apparatus comprising:
a substrate comprising a sub-pixel area;
an inorganic insulating layer located on the substrate, the inorganic insulating layer overlapping the sub-pixel area and comprising a groove;
a plurality of conductive patterns located on the inorganic insulating layer; and
an organic insulating layer covering the inorganic insulating layer and the plurality of conductive patterns,
wherein the plurality of conductive patterns comprises a first conductive pattern connected to a data line that is located on the organic insulating layer, a second conductive pattern connected to a driving voltage line, and a third conductive pattern connected to an upper conductive pattern,
wherein the first conductive pattern, the second conductive pattern, and the third conductive pattern are each surrounded by the groove.

12. The display apparatus of claim 11, wherein:
the inorganic insulating layer comprises a plurality of inorganic insulating patterns spaced apart from each other by the groove,
wherein the first conductive pattern, the second conductive pattern, and the third conductive pattern are respectively located on the plurality of inorganic insulating patterns.

13. The display apparatus of claim 12, wherein the organic insulating layer is located in the groove between the plurality of inorganic insulating patterns.

14. The display apparatus of claim 11, further comprising:
a first semiconductor layer located on the substrate, the first semiconductor layer comprising a silicon semiconductor; and
a second semiconductor layer located on the substrate, the second semiconductor layer comprising an oxide semiconductor,
wherein the first conductive pattern, the second conductive pattern, and the third conductive pattern overlap the first semiconductor layer.

15. The display apparatus of claim 14, wherein the first semiconductor layer comprises:
a source region of a switching transistor connected to the first conductive pattern,
a source region of an operation control transistor connected to the second conductive pattern, and
a drain region of an emission control transistor connected to the third conductive pattern.

16. The display apparatus of claim 11, wherein the driving voltage line and the upper conductive pattern are located on the organic insulating layer.

17. The display apparatus of claim 16, further comprising:
an upper organic insulating layer located on the organic insulating layer, and
a display element layer located on the upper organic insulating layer, the display element layer comprising a display element,
wherein the groove of the inorganic insulating layer overlaps the display element.

18. The display apparatus of claim 17, wherein the display element layer further comprises:
a pixel electrode located on the upper organic insulating layer and connected to the upper conductive pattern;
an intermediate layer located on the pixel electrode; and
a counter electrode covering the intermediate layer.

19. The display apparatus of claim 14, wherein:
the sub-pixel area comprises a first sub-pixel area overlapping a first pixel circuit and a second sub-pixel area overlapping a second pixel circuit, the first sub-pixel area and the second sub-pixel area each being surrounded by the groove,
wherein the first pixel circuit and the second pixel circuit are located on the organic insulating layer,
wherein a connection electrode is located on the organic insulating layer and crosses the groove, the connection electrode connecting the first pixel circuit and the second pixel circuit to each other.

20. The display apparatus of claim 19, further comprising:
a buffer layer located between the substrate and the first semiconductor layer,
wherein the groove surrounding the sub-pixel area exposes a portion of the buffer layer.
